(19) United States
(12) Patent Application Publication
(10) Pub. No.: US 2022/0011568 A1
(43) Pub. Date: Jan. 13, 2022

(54) SCANNING LIGHT MEASURING APPARATUS

(71) Applicant: TOSHIBA TEC KABUSHIKI KAISHA, Shinagawa (JP)

(72) Inventor: Miki Ito, Numazu Shizuoka (JP)

(21) Appl. No.: 16/925,363

(22) Filed: Jul. 10, 2020

(51) Int. Cl. G02B 26/12; G03F 7/20

(52) U.S. Cl. CPC G02B 26/127; G03F 7/70358

(57) ABSTRACT

According to one embodiment, a scanning light measuring apparatus includes a support table, a light-emission control circuit, a light-receiving element, a moving mechanism, and a measurement control circuit. An optical unit is placed on the support table. The optical unit has a synchronous detection sensor that forms scanning light and detects the scanning light. The light-emission control circuit controls the light-emission time of the scanning light. The light-receiving element receives the scanning light. The moving mechanism supports the light-receiving element so as to be movable in a main scanning direction and a rotation direction around an axis orthogonal to the main scanning direction and an optical axis direction of the scanning light. The measurement control circuit moves the light-receiving element in the main scanning direction by the moving mechanism, scans the light-receiving element with the scanning light, acquires an output of the light-receiving element, and measures a scanning light diameter.

### FIELD

Embodiments described herein relate generally to a scanning light measuring apparatus.

### BACKGROUND

An image forming apparatus may scan a photoconductor with a light beam to form an electrostatic latent image. An exposure apparatus that scans a light beam is often unitized. The unitized exposure apparatus accommodates a scanning optical system including, for example, a laser light source, a polygon mirror, and an fθ lens, and a synchronous detection sensor in a housing. The optical performance of the exposure apparatus changes depending on the component accuracy of each component of the exposure apparatus and the placement accuracy of each component in the housing.

In order to improve the productivity of the image forming apparatus, it is desirable that the optical performance of the unitized exposure apparatus can be evaluated accurately and quickly.

### DESCRIPTION OF THE DRAWINGS

FIG. 1 is a schematic view illustrating a configuration example of a scanning light measuring apparatus of an embodiment;

FIG. 2 is a block view illustrating a configuration example of an optical unit and the scanning light measuring apparatus;

FIG. 3 is a schematic view of a cross section of the scanning light measuring apparatus;

FIG. 4 is a schematic view of a cross section taken along the line IV-IV in FIG. 2;

FIG. 5 is a block view of a moving mechanism of the scanning light measuring apparatus;

FIG. 6 is a schematic plan view illustrating scanning light of the scanning light measuring apparatus;

FIG. 7 is a schematic view of a cross section of a light-receiving element in the scanning light measuring apparatus;

FIG. 8 is a schematic view illustrating an example of a timing chart in the scanning light measuring apparatus;

FIG. 9 is a schematic front view illustrating a relationship between scanning light, a photo detector, and the light-receiving element in the scanning light measuring apparatus;

FIG. 10 is a schematic view illustrating an example of an output image of the light-receiving element;

FIG. 11 is a schematic view illustrating an example of measuring a scanning position in the scanning light measuring apparatus;

FIG. 12 is a schematic plan view of an example of defocus measurement in the scanning light measuring apparatus; and

FIG. 13 is a schematic view illustrating an example of an image of scanning light at the time of defocus measurement in the scanning light measuring apparatus.

### DETAILED DESCRIPTION

In general, according to one embodiment, a scanning light measuring apparatus includes a support table, a light-emission control circuit, a light-receiving element, a moving mechanism, and a measurement control circuit. An optical unit is placed on the support table. The optical unit forms scanning light for scanning in a main scanning direction with controllable emission time and scanning speed and has a synchronous detection sensor that detects the scanning light. The light-emission control circuit controls the light-emission time based on a synchronous detection signal from the synchronous detection sensor. The light-receiving element receives the scanning light. The moving mechanism supports the light-receiving element so as to be movable in the main scanning direction and a rotation direction around an axis orthogonal to the main scanning direction and an optical axis direction of the scanning light. The measurement control circuit moves the light-receiving element in the main scanning direction by the moving mechanism, scans the light-receiving element with the scanning light, acquires an output of the light-receiving element, and measures a scanning light diameter of the scanning light based on the output. According to another embodiment, scanning light measuring method for observing light scanned in a main scanning direction with controllable light-emission time and scanning speed by an optical unit having a synchronous detection sensor that detects the light, the method involving a support table on which the optical unit is placed; a light-emission control circuit configured to controlling the light-emission time based on a synchronous detection signal from the synchronous detection sensor; receiving the scanning light by a light-receiving element; supporting the light-receiving element so as to be movable in the main scanning direction and a rotation direction around an axis orthogonal to the main scanning direction and an optical axis direction of the scanning light; moving the light-receiving element in the main scanning direction; scanning the light-receiving element with the scanning light; acquiring an output of the light-receiving element; and measuring a scanning light diameter of the scanning light based on the output.

Hereinafter, the scanning light measuring apparatus of the embodiment will be described with reference to drawings. In the following respective drawings, the same or corresponding components are denoted by the same reference numerals unless otherwise specified.

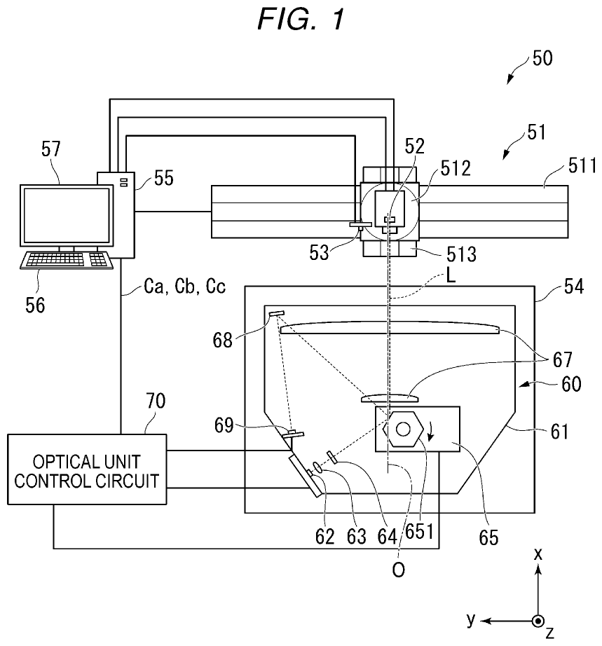

FIG. 1 is a schematic view illustrating a configuration example of the scanning light measuring apparatus of the embodiment.

As illustrated in FIG. 1, a scanning light measuring apparatus 50 of the present embodiment measures scanning light L of an optical unit 60. A scanning optical system included in the optical unit 60 forms the scanning light L. The scanning light L is a beam of light that converges in a spot shape on the image plane of the scanning optical system.

Examples of the measurement performed by the scanning light measuring apparatus 50 include at least one of the scanning light diameter and the scanning position of the scanning light L. As used herein, at least one of X and Y means either one of X and Y, or both X and Y.

Hereinafter, the main scanning direction is defined as the scanning direction of the scanning light L. A sub-scanning direction is a direction orthogonal to the main scanning direction and the direction along the optical axis of the scanning light L (hereinafter, optical axis direction). If there is no risk of misunderstanding, in the plane (beam cross section) orthogonal to the optical axis direction of the scanning light L, the direction orthogonal to the sub-scanning direction may also be referred to as the main scanning direction.

The scanning light diameter may be measured in at least one of the main scanning direction and the sub-scanning direction at a plurality of image heights on the image plane. In the present embodiment, unless otherwise specified, the scanning light diameter means the beam diameter in the main scanning direction and the sub-scanning direction in the beam cross section.

In the measurement of the scanning light diameter, the defocus characteristic may be measured. The defocus characteristic may be measured at a plurality of image heights, and the curvature of field in the optical unit 60 may be obtained.

In the measurement of the scanning position, the deviation of the scanning position in the sub-scanning direction at a plurality of image heights may be measured, and the scanning line bending, the scanning line inclination, and the like of the scanning light L in the optical unit 60 may be obtained.

In the measurement of the scanning position, the deviation of the scanning position in the main scanning direction at a plurality of image heights may be measured, and the fθ characteristic in the optical unit 60 may be obtained.

The optical unit 60 forms the scanning light L for scanning in the main scanning direction. The optical unit 60 scans, for example, the photoconductor of the image forming apparatus to form a latent image on the photoconductor.

The scanning light L of the optical unit 60 may be multi beams, but in the following, an example of a single beam will be described.

The configuration of the optical unit 60 is not particularly limited as long as the single-beam scanning light L can be formed. In the example illustrated in FIG. 1, the optical unit 60 has a housing 61, an LD 62, a collimator lens 63, a cylindrical lens 64, a polygon motor 65, an fθ lens 67, a synchronous detection mirror 68, a synchronous detection sensor 69, and an optical unit control circuit 70.

The positions and directions of the scanning light measuring apparatus 50 and the optical unit 60 placed at a fixed position of the scanning light measuring apparatus 50 will be described below. At that time, the x-axis, y-axis, and z-axis fixed to the scanning light measuring apparatus 50 and the respective positive and negative directions may be referred to.

The y-axis is an axis parallel to the main scanning direction on the image plane of the optical unit 60 where the scanning light L is imaged in a spot shape. The negative direction of the y-axis is the main scanning direction, and the positive direction of the y-axis is opposite to the negative direction. The x-axis is an axis orthogonal to the x-axis on the scanning surface swept by the scanning light L, and is parallel to an optical axis O of the scanning optical system including the fθ lens 67. The positive direction of the x-axis is the direction in which the scanning light L on the optical axis O goes toward the image plane. The negative direction of the x-axis is opposite to the positive direction. The z-axis is an axis orthogonal to the x-axis and the y-axis. The positive direction of the z axis corresponds to the vertically upward direction when the x axis and the y axis are placed in the horizontal plane. The negative direction of the z axis is opposite to the positive direction. The x-axis, y-axis, and z-axis correspond to the three axes in the right-handed coordinate system. The xy plane is a plane including the x-axis and the y-axis. The yz plane is a plane including the y-axis and the z-axis. The zx plane is a plane including the z-axis and the x-axis.

The housing 61 holds the LD 62, the collimator lens 63, the cylindrical lens 64, the polygon motor 65, the fθ lens 67, the synchronous detection mirror 68, and the synchronous detection sensor 69.

The housing 61 has one or more locking portions related to the designed optical axis O of the fθ lens 67 and the position of the image plane. As the shape of the locking portion, for example, an appropriate shape such as a protrusion shape, a pin shape, a hole shape, a groove shape, or a plane shape is used.

The LD 62 is a light source that forms the scanning light L. A laser diode is used as the LD 62. The LD 62 is placed on the side surface of the housing 61.

The collimator lens 63 collimates the laser light emitted from the LD 62. The collimator lens 63 is placed in the housing 61 so as to be coaxial with the optical axis of the laser light.

The cylindrical lens 64 has a refracting power only in the sub-scanning direction and condenses the laser light collimated by the collimator lens 63 in the sub-scanning direction. The cylindrical lens 64 is placed in the housing 61.

For example, on the optical path between the collimator lens 63 and the cylindrical lens 64, a diaphragm (aperture) that defines the light beam diameters of the laser light in the main scanning direction and the sub-scanning direction may be placed.

The polygon motor 65 has a polygon mirror 651 whose mirror surface is formed in a polygonal shape, and a rotor to which the polygon mirror 651 is fixed. The rotor of the polygon motor 65 rotates about a rotation axis parallel to the z-axis in response to a control signal from the outside. When the rotor rotates, the polygon mirror 651 fixed to the rotor rotates in the main scanning direction. In the example illustrated in FIG. 1, the polygon mirror 651 rotates in the rotation direction (clockwise direction in FIG. 1) in which a right-handed screw advances in the negative direction on the z-axis.

The polygon mirror 651 and the fθ lens 67 are a scanning optical system in the optical unit 60.

The mirror surface of the polygon mirror 651 of the polygon motor 65 is placed at a position where the laser light condensed by the cylindrical lens 64 in the sub-scanning direction can be deflected at the condensing position.

he fθ lens 67 has an fθ characteristic in the main scanning direction. For example, the fθ lens 67 is an imaging optical system having different refractive powers in the main scanning direction and the sub-scanning direction. The fθ lens 67 has a refracting power that makes the image plane in the main scanning and the deflection position of the polygon mirror 651 optically conjugate with each other in the sub-scanning direction.

FIG. 1 illustrates the two-element fθ lens 67, but the fθ lens 67 is not limited to the two-element configuration. For example, the fθ lens 67 may be composed of one element, or maybe composed of three or more elements. The configuration of each lens surface of the fθ lenses 67 is also not particularly limited.

The synchronous detection mirror 68 is placed in the housing 61 on the optical path of the scanning light L emitted from the fθ lens 67. The synchronous detection mirror 68 reflects the scanning light L toward the synchronous detection sensor 69 on the upstream side in the main scanning direction.

The synchronous detection sensor 69 is placed in the housing 61 on the optical path of the scanning light L reflected by the synchronous detection mirror 68. The synchronous detection sensor 69 detects the arrival of the scanning light L at a specific image height.

As the synchronous detection sensor 69, a photodiode having a good response speed is used. The synchronous detection sensor 69 is electrically connected to the optical unit control circuit 70. The synchronous detection sensor 69 sends an output signal resulting from the incidence of the scanning light L to the optical unit control circuit 70.

The optical unit control circuit 70 will be described.

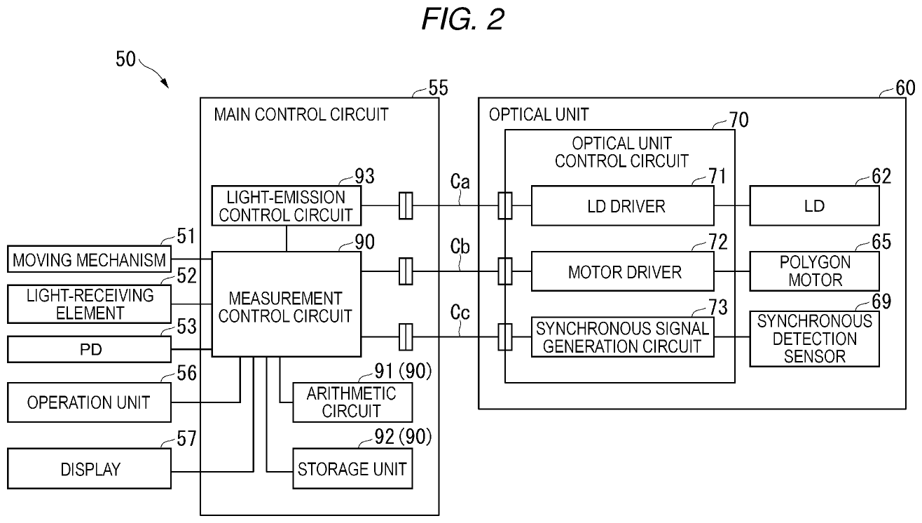

FIG. 2 is a block view illustrating a configuration example of the optical unit and the scanning light measuring apparatus of the embodiment. In FIG. 2, a photo detector 53 is abbreviated as PD 53.

As illustrated in FIG. 2, the optical unit control circuit 70 has an LD driver 71, a motor driver 72, and a synchronous signal generation circuit 73.

The LD driver 71 is electrically connected to the LD 62. The LD driver 71 is communicatively connected to a main control circuit 55 via a connection cable Ca. The LD driver 71 turns on or off the LD 62 according to the control signal from the main control circuit 55. The LD driver 71 can change the light-emission time of the LD 62 according to the control signal from the main control circuit 55.

The motor driver 72 is electrically connected to the polygon motor 65. The motor driver 72 is communicatively connected to the main control circuit 55 via a connection cable Cb. The motor driver 72 rotates the rotor of the polygon motor 65 according to the control signal from the main control circuit 55. The motor driver 72 can change the rotation speed of the rotor according to the control signal from the main control circuit 55.

The synchronous signal generation circuit 73 is electrically connected to the synchronous detection sensor 69. The synchronous signal generation circuit 73 is communicatively connected to the main control circuit 55 via a connection cable Cc. The synchronous signal generation circuit 73 binarizes the output signal sent from the synchronous detection sensor 69 to generate a synchronous detection signal. The synchronous detection signal is sent to the main control circuit 55.

In FIG. 1, the optical unit control circuit 70 is schematically depicted outside the housing 61. The mounting form of the optical unit control circuit 70 is not limited to the illustrated form. The mounting form of the optical unit control circuit 70 can be an appropriate form according to the product form of the optical unit 60.

For example, the optical unit control circuit 70 may be fixed inside or outside the housing 61 of the optical unit 60.

For example, the optical unit control circuit 70 may be divided into three substrates having the LD driver 71, the motor driver 72, and the synchronous signal generation circuit 73, respectively. In this case, the LD 62, the rotor of the polygon motor 65, and the synchronous detection sensor 69 are individually mounted on the three substrates. The connection cables Ca, Cb, and Cc may be three cables respectively connected to three substrates, or one or two branch cables having a many-to-one connector.

For example, the LD 62 and the synchronous detection sensor 69 may be mounted on the same substrate.

As illustrated in FIG. 1, the scanning light measuring apparatus 50 has a support table 54, a light-receiving element 52, a moving mechanism 51, a photo detector 53, and a main control circuit 55. In the present embodiment, the xy plane in the scanning light measuring apparatus 50 is a horizontal plane.

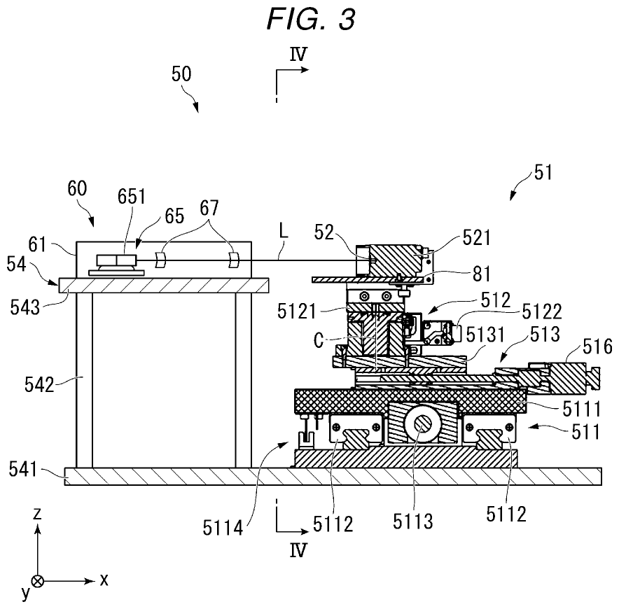

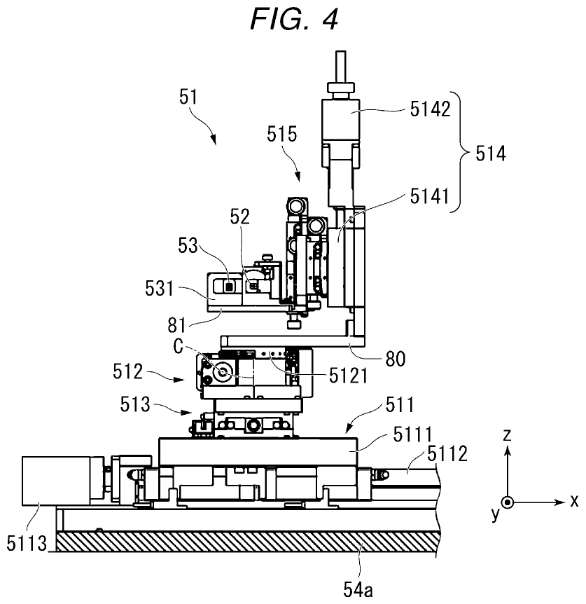

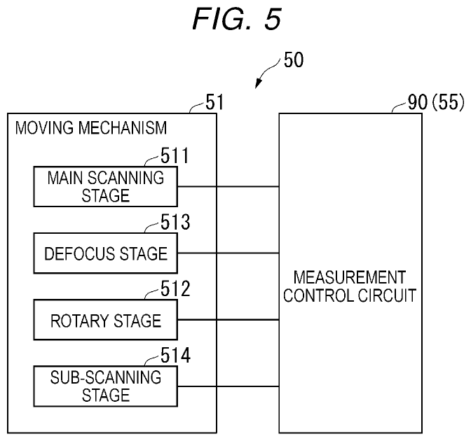

FIG. 3 is a schematic view of a cross section of the scanning light measuring apparatus of the embodiment. FIG. 4 is a schematic view of a cross section taken along the line IV-IV in FIG. 2. FIG. 5 is a block view of a moving mechanism of the scanning light measuring apparatus of the embodiment.

The support table 54 supports the optical unit 60 from below and the optical unit 60 is placed in a fixed position. At the fixed position of the optical unit 60, the designed optical axis O in the optical unit 60 is parallel to the x-axis, and the image plane of the scanning light L is formed parallel to the y axis at a predetermined distance from the support table 54.

As illustrated in FIG. 3, the support table 54 has a base 541, legs 542, and a support plate 543.

The base 541 has a plate shape placed horizontally. The legs 542 extending vertically upward are fixed to the upper surface of the base 541. The legs 542 are, for example, columnar, and three or more legs are provided. The plate-shaped support plate 543 is fixed to each upper end of the leg 542.

The support plate 543 has a locking portion that locks the locking portion of the optical unit 60, and a fixing portion that fixes the optical unit 60 on the support plate 543.

The shape of the locking portion of the support plate 543 is not particularly limited as long as the optical unit 60 can be placed at a fixed position.

For example, the shape of the locking portion of the support plate 543 may be the same as the locking portion used for positioning the optical unit 60 in the image forming apparatus in which the optical unit 60 is mounted.

For example, the locking portion of the support plate 543 may be provided so as to be positionally adjustable or replaceable so that the optical unit 60 having various types of locking portions can be locked.

For example, the fixing portion of the support plate 543 may be the same as the fixing portion that fixes the optical unit 60 in the image forming apparatus in which the optical unit 60 is mounted.

For example, the fixing portion of the support plate 543 may be a fixing surface on which the optical unit 60 is placed and a female screw for screwing.

For example, the fixed portion of the support plate 543 may be a clamp mechanism that brings the locking portion of the housing 61 into contact with the locking portion of the support plate 543 during measurement.

As illustrated in FIGS. 1 and 3, the light-receiving element 52 receives the scanning light L. As the light-receiving element 52, various light-receiving elements corresponding to the type of measurement of the scanning light measuring apparatus 50 can be used.

For example, as the light-receiving element 52, a two-dimensional image sensor may be used. In the two-dimensional image sensor, a large number of light-receiving portions forming pixels are two-dimensionally placed, and the two-dimensional image sensor outputs two-dimensional image data according to the amount of light received by each light-receiving portion. The two-dimensional image sensor is sometimes called an area sensor. Examples of the two-dimensional image sensor include a CMOS sensor, a CCD sensor, a laser measuring instrument, and the like.

The resolution determined by the pixel pitch of the two-dimensional image sensor is not particularly limited as long as the two-dimensional image data of the scanning light L can be acquired with a required measurement accuracy.

When the light-receiving element 52 is a two-dimensional image sensor, both the scanning light diameter and the scanning position of the scanning light L can be measured in the main scanning direction and the sub-scanning direction.

For example, the two-dimensional image sensor may be incorporated in an imaging unit including a drive circuit, an image processing circuit, and the like.

For example, when the scanning light diameter may be measured in either the main scanning direction or the sub-scanning direction, as the light-receiving element 52, a photo detector combined with a mask, a one-dimensional image sensor (linear sensor), or the like can be used. The same applies when the scanning position may be measured in either the main scanning direction or the sub-scanning direction.

Hereinafter, an example in which the light-receiving element 52 is a two-dimensional image sensor will be described.

The moving mechanism 51 movably supports the light-receiving element 52. The moving direction of the light-receiving element 52 by the moving mechanism 51 includes the main scanning direction and the rotation direction around an axis orthogonal to the main scanning direction and the optical axis direction of the scanning light L.

As illustrated in FIGS. 1, 3, and 4, in the present embodiment, the moving mechanism 51 has a main scanning stage 511, a defocus stage 513, a rotary stage 512, and a sub-scanning stage 514 (see FIG. 4).

The main scanning stage 511, the defocus stage 513, the rotary stage 512, and the sub-scanning stage 514 are stacked on the base 541 in this order.

As illustrated in FIG. 3, the light-receiving element 52 is fixed to a mounting plate 81 that interlocks with the sub-scanning stage 514 via a holder 521.

The main scanning stage 511 moves the light-receiving element 52 in the main scanning direction. It is more preferable that the moving range of the main scanning stage 511 is wider than the valid scanning area of the scanning light L in the main scanning direction.

For example, as illustrated in FIG. 3, the main scanning stage 511 has a slide rail 5112, a slider 5111, a feed mechanism 5113, and a linear encoder 5114.

The slide rail 5112 extends parallel to the y-axis and is placed on the base 541. The slider 5111 is fixed on the slide rail 5112 for movement along the y-axis. The feed mechanism 5113 moves the slider 5111 along the y-axis, and the linear encoder 5114 detects the position of the slider 5111 in the y-axis direction. The linear encoder 5114 may be replaced with another position detection device that detects the position of the slider 5111 in the y-axis direction. Depending on the measurement application, the main scanning stage 511 may not have the linear encoder 5114.

The defocus stage 513 moves the light-receiving element 52 along the x-axis. The defocus stage 513 is fixed to the slider 5111 of the main scanning stage 511.

The defocus stage 513 has a slider 5131 that moves along the x-axis and a feed motor 5132 that moves the slider 5131. The feed motor 5132 has a built-in encoder and can detect the movement position of the slider 5131 along the x-axis.

When the defocus measurement of the scanning light L is not performed, the defocus stage 513 can be omitted.

The rotary stage 512 rotates the light-receiving element 52 around an axis C parallel to the z axis. The rotary stage 512 is used to adjust the incident angle of the scanning light L on the light-receiving element 52. In the present embodiment, the rotary stage 512 is used to make the scanning light L on the xy plane be incident on the light-receiving surface of the light-receiving element 52 from a direction substantially orthogonal to the light-receiving surface. The rotary stage 512 is fixed to the slider 5131 of the defocus stage 513.

The rotary stage 512 has a rotor 5121 that rotates around the axis C and a rotary motor 5122 that rotates the rotor 5121. The rotary motor 5122 has a built-in encoder and can detect the rotational position of the rotor 5121 around the axis C.

As illustrated in FIG. 4, the sub-scanning stage 514 moves the light-receiving element 52 along the z-axis. The sub-scanning stage 514 is fixed to the rotor 5121 of the rotary stage 512 via a connecting member 80.

The sub-scanning stage 514 has a slider 5141 that moves in the z direction and a feed motor 5142 that moves the slider 5141. The feed motor 5142 has a built-in encoder and can detect the movement position of the slider 5141 along the z-axis.

When the moving mechanism 51 has the sub-scanning stage 514 as in the present embodiment, since it is possible to measure the scanning light L of the plurality of types of optical units 60 having different scanning surface heights of the scanning light L on the support table 54 in the sub-scanning direction, versatility is improved.

For example, when the scanning light L is multi beams, the scanning position of each scanning light L in one optical unit 60 is deviated in the sub-scanning direction. When the moving mechanism 51 has the sub-scanning stage 514, the scanning position of each scanning light L with respect to the photo detector 53 and the light-receiving element 52 in the sub-scanning direction can be aligned, and the measurement accuracy can be easily improved.

When it is not necessary to move the scanning position of the scanning light L in the photo detector 53 and the light-receiving element 52 in the sub-scanning direction, the sub-scanning stage 514 can be omitted.

The mounting plate 81 is fixed to the slider 5141 via an adjustment stage 515. The mounting plate 81 is a flat plate shape that extends horizontally from the adjustment stage 515. The mounting plate 81 is above the rotary stage 512.

The adjustment stage 515 finely adjusts the position or posture of the mounting plate 81 with respect to the slider 5141 of the sub-scanning stage 514. As the adjustment stage 515, one or more stages having the degree of freedom of movement required for adjustment are used. The adjustment stage 515 may be a manual stage or an electric stage.

For example, the adjustment stage 515 may be adjustable to move the light-receiving surface of the light-receiving element 52 fixed on the mounting plate 81 onto the axis C.

If the position of the light-receiving element 52 can be adjusted when the light-receiving element 52 is mounted on the mounting plate 81, the adjustment stage 515 may be omitted.

As illustrated in FIG. 3, the light-receiving element 52 is fixed on the mounting plate 81 by being held by the holder 521. The light-receiving element 52 is placed in the center of the light-receiving surface in the width direction so that the axis C passes through. When the rotary stage 512 rotates, the light-receiving element 52 rotates around the center of the light-receiving surface in the width direction.

As illustrated in FIG. 4, on the mounting plate 81, the photo detector 53 is placed apart from the light-receiving element 52 on the upstream side in the main scanning direction (the positive direction side of the y-axis with respect to the light-receiving element 52). The photo detector 53 is fixed to a holder 531 fixed on the mounting plate 81.

The center of the light-receiving surface of the photo detector 53 is aligned with the same height of the center of the light-receiving surface of the light-receiving element 52 with respect to the mounting plate 81.

The photo detector 53 detects that the scanning light L is arrived at a certain position on the upstream side of the light-receiving element 52 and sends a detection signal to the main control circuit 55. A part of the light-receiving surface of the photo detector 53 may be covered with a slit-shaped or edge-shaped mask extending along the z-axis. In this case, it is possible to reduce variations in the detection position of the scanning light L in the photo detector 53, and thus the measurement accuracy of the scanning position can be improved.

In the present embodiment, the distance between the position of the scanning light L detected by the photo detector 53 and the center of the light-receiving element 52 in the direction along the y-axis is d.

A distance d is preferably as short as possible, and may be, for example, 3.0 mm or more and 350.0 mm or less.

The main control circuit 55 controls the light-emission time and the scanning speed of the scanning light L in the optical unit 60, and the overall operation of the scanning light measuring apparatus 50.

As illustrated in FIG. 2, the main control circuit 55 has a light-emission control circuit 93 and a measurement control circuit 90.

The light-emission control circuit 93 controls the light-emission time of the scanning light L. The control of the light-emission control circuit 93 includes control of the light-emission start time and the light-emission end time of the scanning light L. The light-emission control circuit 93 can send a pulse signal to the LD 62 to turn on the scanning light L in a spot shape.

The light-emission control circuit 93 is electrically connected to the LD driver 71 via the connection cable Ca.

The light-emission control circuit 93 sends a control signal to the LD driver 71 to start or end lighting in response to the control signal from the measurement control circuit 90.

Details of the control of the light-emission control circuit 93 will be described together with the measurement operation of the scanning light measuring apparatus 50.

The measurement control circuit 90 is communicatively connected to an operation unit 56 and controls the scanning speed of the scanning light L and the overall operation of the scanning light measuring apparatus 50 based on the inputs from the operation unit 56. The measurement control circuit 90 has an arithmetic circuit 91 and a storage unit 92.

The operation unit 56 has, for example, an input device such as a keyboard and a touch panel, and a measurer can input information necessary for measurement in the scanning light measuring apparatus 50.

Inputs from the operation unit 56 include, for example, a measurement type, a measurement condition corresponding to the measurement type, a measurement start input, and the like.

The measurement control circuit 90 is communicatively connected to a display 57 that can display information such as measurement conditions and measurement values.

The measurement control circuit 90 is electrically connected to the motor driver 72 via the connection cable Cb, and the synchronous signal generation circuit 73 via the connection cable Cc.

The measurement control circuit 90 is further communicably connected to the light-emission control circuit 93, the light-receiving element 52, the photo detector 53, and the moving mechanism 51 and controls the respective operations.

The main control performed by the measurement control circuit 90 will be briefly described.

For example, the measurement control circuit 90 sends a control signal to the motor driver 72 to rotate the rotor of the polygon motor 65 at a constant speed. It is more preferable that the rotation speed of the polygon motor 65 is the rotation speed when the polygon motor 65 is mounted on the image forming apparatus and used (hereinafter, in actual use). However, if the rotation unevenness is equal to or less than that during actual use, a rotation speed different from the rotation speed in actual use may be used.

The measurement control circuit 90 sends a control signal to the light-emission control circuit 93 based on the synchronous detection signal from the synchronous signal generation circuit 73 and the detection signal from the photo detector 53.

The measurement control circuit 90 acquires two-dimensional image data based on the output of the light-receiving element 52 when the light-receiving element 52 is scanned by the scanning light L. The measurement control circuit 90 stores the two-dimensional image data in the storage unit 92. The measurement control circuit 90 sends, to the arithmetic circuit 91, a control signal for calculating at least one of the scanning light diameter and the scanning position of the scanning light L based on the two-dimensional image data stored in the storage unit 92.

As illustrated in FIG. 5, the measurement control circuit 90 is communicatively connected to the main scanning stage 511, the defocus stage 513, the rotary stage 512, and the sub-scanning stage 514.

The measurement control circuit 90 sends a control signal to the feed mechanism 5113 of the main scanning stage 511 to move the slider 5111 along the y-axis. The measurement control circuit 90 acquires the position information of the slider 5111 from the linear encoder 5114. The acquired position information is sent to the storage unit 92.

When measuring the defocus characteristic, the measurement control circuit 90 sends a control signal to the feed motor 5132 of the defocus stage 513 to move the slider 5131 along the x-axis.

The measurement control circuit 90 sends a control signal to the rotary stage 512 according to the image height to be measured and rotates the rotor 5121. The rotational position of the rotor 5121 at each image height is controlled so that the light-receiving surface of the light-receiving element 52 is substantially orthogonal to the optical axis direction of the scanning light L in the main scanning direction. The substantially orthogonal angle is, for example, from −10.0 degrees to +10.0 degrees. It is more preferable that the substantially orthogonal angle is from −0.5 degrees to +0.5 degrees.

When it is necessary to change the position of the light-receiving element 52 in the sub-scanning direction with respect to the scanning light L, the measurement control circuit 90 sends a control signal to the sub-scanning stage 514 to move the slider 5141 in the z-axis direction.

Details of the control performed by the measurement control circuit 90 will be described along with the operation of the scanning light measuring apparatus 50.

The arithmetic circuit 91 performs various kinds of arithmetic processing based on the control signal from the measurement control circuit 90.

For example, the arithmetic circuit 91 calculates at least one of the scanning light diameter and the scanning position based on the image data acquired by the measurement control circuit 90 from the light-receiving element 52.

The device configuration of the main control circuit 55 is configured by at least one of a computer including a CPU, a memory, an input/output interface, and an external storage device, and other hardware.

For example, when a computer is used in the main control circuit 55, the control function of the main control circuit 55 is realized by executing a control program stored in the memory of the computer. The storage unit 92 may be at least one of a memory and an external storage device.

The operation of the scanning light measuring apparatus 50 will be described.

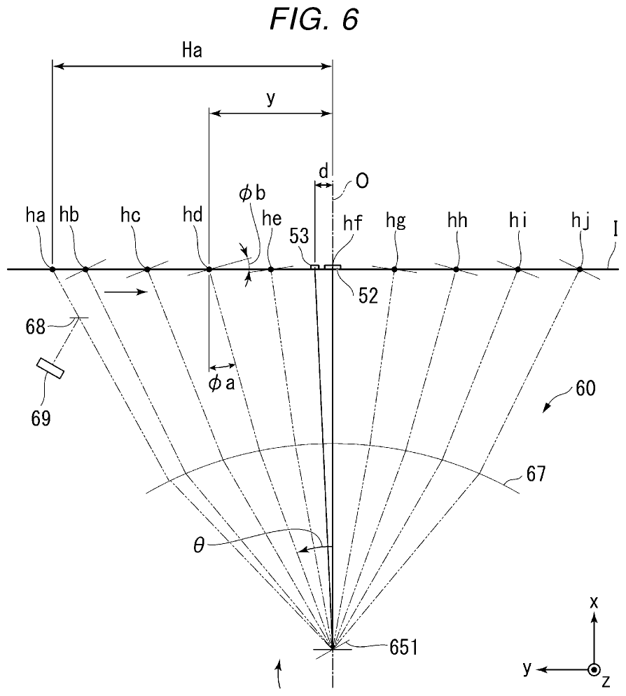

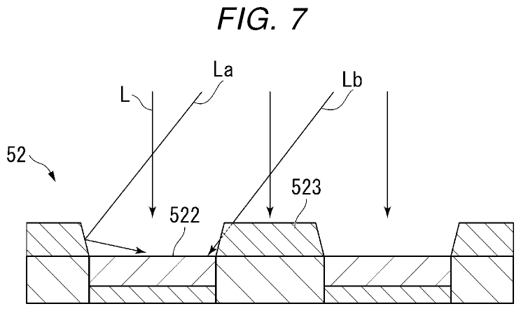

FIG. 6 is a schematic plan view illustrating scanning light of the scanning light measuring apparatus of the embodiment. FIG. 7 is a schematic view of a cross section of the light-receiving element in the scanning light measuring apparatus of the embodiment.

In order to perform scanning light measurement of the optical unit 60 using the scanning light measuring apparatus 50, the measurer inputs a measurement type through the operation unit 56. An example of measuring the scanning light diameter and the scanning position on the image plane will be described below.

The scanning light measuring apparatus 50 scans the scanning light L by the optical unit 60 to measure the scanning light diameter and the scanning position. The main control circuit 55 rotates the polygon motor 65 to generate the scanning light L at a measurement position. The lighting control of the LD 62 in the optical unit 60 is performed in the same manner as when the LD 62 is mounted in the image forming apparatus. The scanning light L is continuously lit until the synchronous detection sensor 69 receives the scanning light L. When the synchronous detection sensor 69 detects the arrival of the scanning light L, a synchronous detection signal is generated. Thereafter, the lighting control of the scanning light L is performed based on the synchronous detection signal.

For example, as illustrated in FIG. 6, it is assumed that measurement is performed at an image height of 0 mm on the optical axis O. When the image height of the synchronous detection sensor 69 is Ha, the main control circuit 55 controls the moving mechanism 51 so that the center of the light-receiving element 52 can be moved to an image height of 0 mm on an image plane I when scanning the scanning light L.

In the scanning light measuring apparatus 50, the measurement may be performed at one or more image heights in one scan. In the scanning light measuring apparatus 50, the measurement may be performed at one image height every one or more scans.

For example, in the scanning light measuring apparatus 50, the measurement may be performed at one image height for each of a plurality of scans that take time. When the rotation speed of the polygon motor 65 is brought closer to the rotation speed in actual use, the speed of the main scanning stage 511 is often lower. When a two-dimensional image sensor is used as the light-receiving element 52, it is necessary to consider the time required for image transfer. For example, when a 30 FPS camera is used as the light-receiving element 52, it takes about 33 msec to transfer an image, and thus a measurement cycle needs to be longer than 33 msec.

For example, from the viewpoint that the measurement time can be shortened, the measurement maybe performed at one image height every one scan.

For example, when the number of mirror surfaces of the polygon mirror 651 is N, the measurement may be performed once for k×N times of scan, where k is a natural number. In this case, a measurement error due to the difference in the mirror surfaces is eliminated.

In the following, an example will be described in which one image height is measured for each measurement cycle that is longer than the scanning cycle of one scan. In the example illustrated in FIG. 6, for example, the measurement is performed at 9 image heights at equal intervals from an image height hb to an image height hj in 9 measurement cycles. However, the number of image heights to be measured is not limited to 9. For example, the measurement position may be set so that the measurement interval is 1 mm. The intervals between measurement positions are not limited to equal intervals. For example, the measurement interval may be narrowed near the image height where the scanning light diameter is likely to change.

For example, if the number of measurement positions is 9, and if the main scanning stage 511 moves within the range of the measurement position while performing 9 scans with a measurement cycle, all the measurement can be completed while the main scanning stage 511 is moved once in the negative direction of the y-axis.

As illustrated in FIG. 6, the main control circuit 55 controls the rotary stage 512 of the moving mechanism 51 so that the light-receiving surface of the light-receiving element 52 is substantially orthogonal to the scanning light L at each measurement position. In the optical unit 60, when the polygon mirror 651 rotates at a constant speed, the scanning light L scans the image plane I at a constant speed. When the angle of the scanning light L measured from the optical axis O is θ and the focal length of the fθ lens 67 is f, a designed image height y of the scanning light L has a relation of y=f×θ. An incident angle ϕa of the scanning light L with respect to the image plane I at the image height y is a function of y and is known in advance from the optical layout of the scanning optical system.

If the measurement position is the image height y, the main control circuit 55 rotates the light-receiving element 52 with respect to the image plane I by ϕb which is substantially equal to ϕa.

As illustrated in FIG. 7, a plurality of pixels 522 are arranged on the light-receiving surface of the light-receiving element 52, and a light shielding film 523 projects between the pixels 522. The light shielding film 523 prevents the scanning light L from being incident on the light-receiving element 52 other than the pixels 522.

For example, when the incident angle on the light-receiving surface of the light-receiving element 52 is large, such as scanning lights La and Lb, light reflected by the light shielding film 523 may be incident on the pixels 522, or light that should be incident on the pixels 522 may be blocked by the light shielding film 523.

When the scanning light L is made incident on the light-receiving surface of the light-receiving element 52 substantially vertically, the incident light of the pixels 522 is limited to the range of the size of the pixel, and thus the measurement accuracy is improved.

An example of lighting control of the scanning light L will be described.

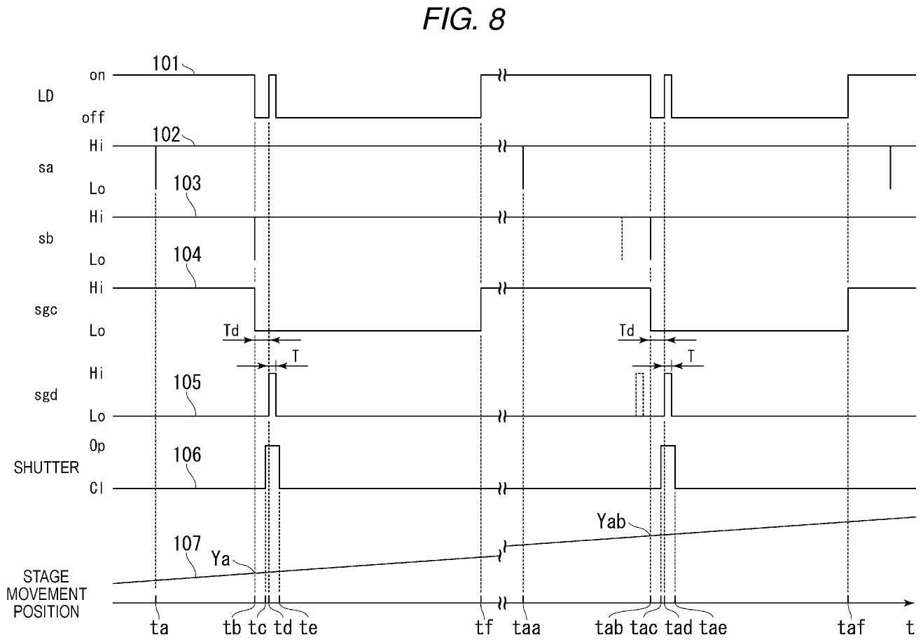

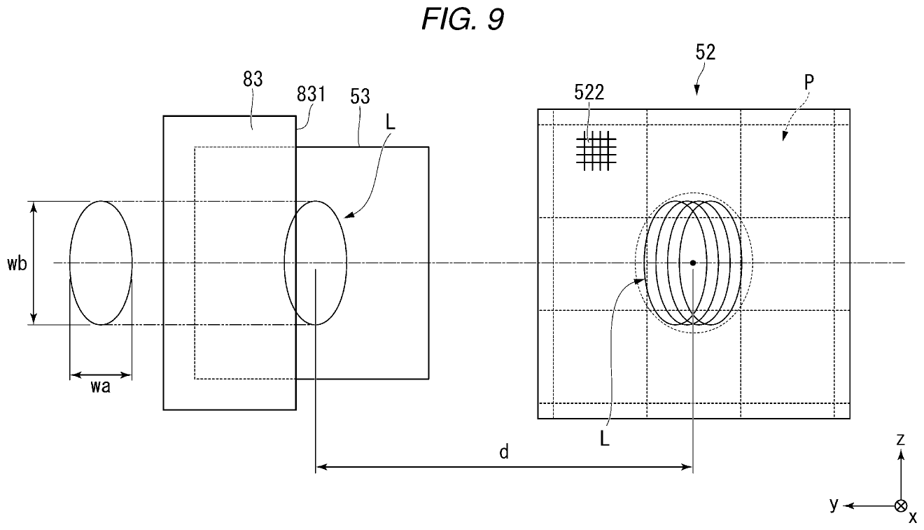

FIG. 8 is a schematic view illustrating an example of a timing chart in the scanning light measuring apparatus of the embodiment. A horizontal axis t of FIG. 8 is time. The time on the horizontal axis increases in the order of ta, . . . , tf, taa, . . . , taf. FIG. 9 is a schematic front view illustrating a relationship between the scanning light, the photo detector, and the light-receiving element in the scanning light measuring apparatus of the embodiment.

When the measurement is started, the moving mechanism 51 starts moving the main scanning stage 511 in the negative direction from the positive direction side of the y-axis at a predetermined speed.

As indicated by the polygonal line 104 in FIG. 8, the measurement control circuit 90 sets a control signal sgc to the light-emission control circuit 93 to high (Hi in FIG. 8) and sets a control signal sgd to low (Lo in FIG. 8). The light-emission control circuit 93 turns on the LD 62 when the logical sum of the control signals sgc and sgd is Hi, and thus the LD 62 is turned on (on in FIG. 8) as indicated by the polygonal line 101 of FIG. 8, and the scanning light L is generated. When the scanning light L reaches an image height ha at the time ta, the scanning light L is incident on the synchronous detection sensor 69 (see FIG. 6).

As indicated by the polygonal line 102, the synchronous detection sensor 69 generates a synchronous detection signal sa at the time ta and sends the synchronous detection signal sa to the measurement control circuit 90. The measurement control circuit 90 measures time based on the synchronous detection signal sa.

As illustrated in FIG. 9, when the scanning light L is incident on the photo detector 53, the photo detector 53 generates a detection signal sb (see the polygonal line 103 in FIG. 8). The detection signal sb is sent to the measurement control circuit 90. The measurement control circuit 90 measures the time tb when the detection signal sb is generated.

Upon receiving the detection signal sb, the measurement control circuit 90 acquires position information of the main scanning stage 511 and turns off the LD 62 (off in FIG. 8). Position information Ya of the main scanning stage 511 at the time tb (see the straight line 107) is acquired from the linear encoder 5114. The turning off of the LD 62 is realized by setting the control signal sgc sent to the light-emission control circuit 93 to Lo. The control signal sgc is set to Hi at the time tf just before the scanning light L reaches the image height ha in the next scan. The control signal sgc turns on the LD 62 to obtain the synchronous detection signal sa during the measurement period.

As indicated by the polygonal line 105, the measurement control circuit 90 sets the control signal sgd to Hi for a predetermined lighting time T at the time td after a predetermined time Td from the time tb with reference to the detection signal sb.

The time Td is a designed time until when the scanning light L reaches the central portion of the light-receiving element 52 from the detection position in the photo detector 53. The time Td is predetermined based on the relative speed difference between the main scanning stage 511 and the scanning light L and the distance d from the detection position in the photo detector 53 to the center of the light-receiving element 52.

As illustrated in FIG. 9, in the present embodiment, a part of the photo detector 53 is covered with a light shielding plate 83. The detection position in the photo detector 53 is a position slightly advanced from an edge 831 of the light shielding plate 83 in the negative direction of the y-axis according to the sensitivity of the photo detector 53, the light amount of the scanning light L, and the scanning speed.

The time for which the control signal sgd is set to Hi is the lighting time required for measuring the scanning light diameter. For example, when measuring the scanning light diameter corresponding to a stationary beam diameter, the lighting time T is determined in advance by simulation or experiment so that the integrated light amount on the light-receiving element 52 approaches the stationary beam diameter. For example, when measuring a light amount distribution corresponding to one dot in the image forming apparatus, the lighting time T is set to the time corresponding to the lighting time per dot in actual use.

The measurement control circuit 90 opens the shutter of the light-receiving element 52 so that the scanning light L is received by the light-receiving element 52 with reference to the detection signal sb as indicated by the polygonal line 106 (Op in FIG. 8). The shutter of the light-receiving element 52 is opened before the time td and closed at the time to after the time (td+T) (Cl in FIG. 8).

The shutter of the light-receiving element 52 may be a mechanical shutter or an electronic shutter.

As illustrated in FIG. 9, the light-receiving element 52 acquires a light-receiving distribution according to the integrated light amount by scanning for the lighting time T. For reference, FIG. 9 illustrates the size of a rectangular pixel P in the image forming apparatus by a broken line. The stationary beam diameter of the scanning light L on the image plane I is wa in the main scanning direction and wb in the sub-scanning direction.

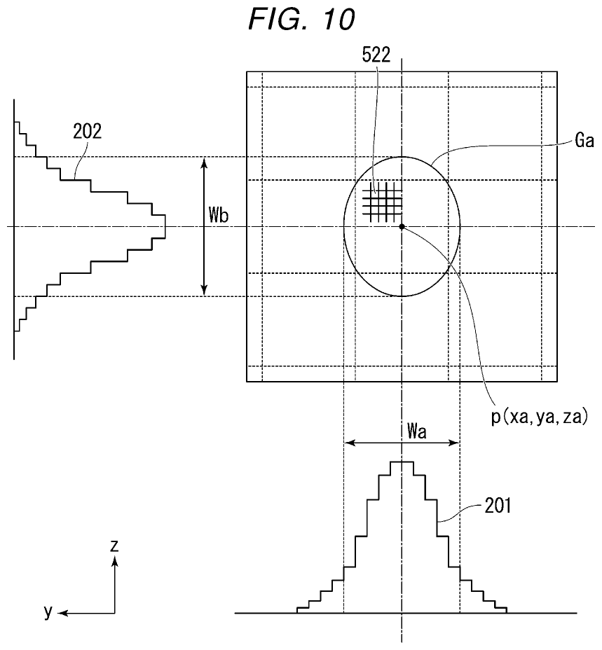

FIG. 10 is a schematic view illustrating an example of an output image of the light-receiving element in the scanning light measuring apparatus of the embodiment.

As illustrated schematically in FIG. 10, image data Ga output from the light-receiving element 52 represents a substantially elliptical image. The light intensity distributions in the main scanning direction and the sub-scanning direction passing through a center p of the image data Ga are bell-shaped as indicated by the polygonal lines 201 and 202.

The image data Ga is stored in the storage unit 92. The image data Ga stored in the storage unit 92 is arithmetically processed by the arithmetic circuit 91 based on the control signal from the measurement control circuit 90 to calculate scanning light diameters Wa and Wb and a scanning position (xa, ya, za).

The scanning light diameters Wa and Wb are obtained as a range in which the light intensities in the main scanning direction and the sub-scanning direction are equal to or higher than a predetermined threshold value.

The scanning position (xa, ya, za) is obtained by obtaining the position of the intensity center from each intensity value of the image data Ga and converting the position to the coordinate value of the xyz coordinate system in the scanning light measuring apparatus 50.

The intensity peak of the image data Ga is obtained at the time (td+T/2). The position of the slider 5111 of the main scanning stage 511 at the time (td+T/2) is obtained by adding the distance moved by the slider 5111 during the time (td+T/2−tb) to the position information acquired by the measurement control circuit 90 at the time tb. By reducing the distance d, the time (td+T/2−tb) is shortened, and the speed fluctuation of the main scanning stage 511 during the time (td+T/2−tb) can be ignored.

The positional relationship between the position of the slider 5111 and each pixel 522 of the light-receiving element 52 is calibrated when the light-receiving element 52 is fixed to the moving mechanism 51.

Each calculation result by the arithmetic circuit 91 is sent to the measurement control circuit 90.

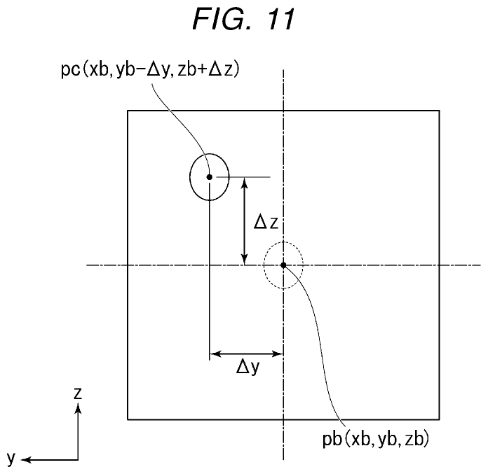

FIG. 11 is a schematic view illustrating an example of measuring a scanning position in the scanning light measuring apparatus of the embodiment.

As illustrated in FIG. 11, when a manufacturing error occurs in the fθ lens 67, the scanning position of the scanning light L is a value deviated from a designed scanning position pb (xb, yb, zb) indicated by the broken line, for example, pc (xb, yb−Δy, zb+Δz) indicated by the solid line.

Consequently, the measurement at one measurement position ends.

When the scanning for the measurement period is performed, the same measurement is performed at the next measurement position on the downstream side in the scanning direction. The main scanning stage 511 moves to the next measurement position on the downstream side when the measurement cycle elapses.

The LD 62 is turned on at the time tf by the control signal sgc and is turned off while the control signal sgc is Lo until the next measurement. In the next measurement, a synchronous detection signal is generated at the time taa. Measuring time is started based on the synchronous detection signal, and substantially the same control as from the time ta to the time tf is performed from the time taa to the time taf corresponding to each time. The times taa, tab, tac, tad, tae, and taf correspond to the times ta, tb, tc, td, te, and tf, respectively.

The time Td and the lighting time T are the same as in the previous scan. The movement position of the main scanning stage 511 at the time tab is Yab=Ya+V×(tab−tb), where V is the moving speed of the stage.

When the measurement ends at each measurement position, the measurement of the scanning light of the optical unit 60 ends.

The scanning light diameters in the main scanning direction and the sub-scanning direction at each measurement position correlate with the stationary beam diameters in the main scanning direction and the sub-scanning direction in the direction orthogonal to the optical axis of the scanning light L on the image plane I of the optical unit 60. From the measurement results of the scanning light diameters in the main scanning direction and the sub-scanning direction, it is possible to determine whether the stationary beam diameter of the optical unit 60 is within the standard.

The value of Δy at each measurement position represents the fθ characteristic including the rotation unevenness of the polygon motor 65 in the optical unit 60. From the measurement result of Δy at each measurement position, it is possible to determine whether the fθ characteristic of the optical unit 60 is within the standard.

According to the value of Δz at each measurement position, the scanning line bending amount and the scanning line inclination amount with respect to the mounting reference of the optical unit 60 are calculated.

The measurement control circuit 90 displays the obtained measured value on the display 57.

The measurer can know the optical characteristics of the optical unit 60 by looking at the display on the display 57.

The scanning light measuring apparatus 50 can also perform defocus measurement with respect to the scanning light diameter and the scanning position.

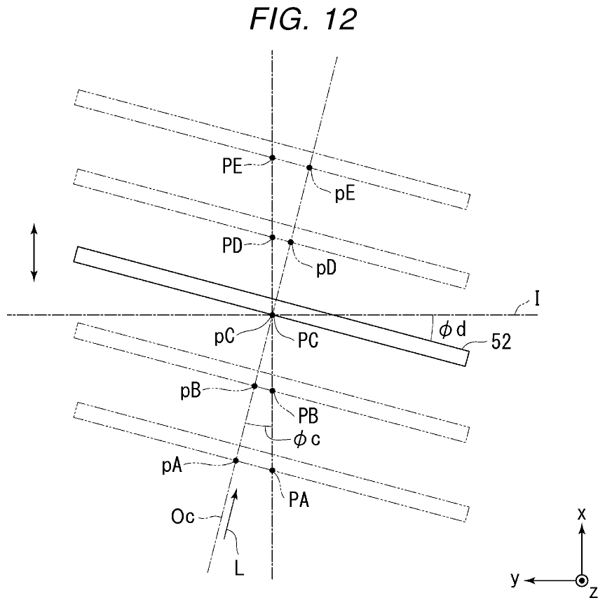

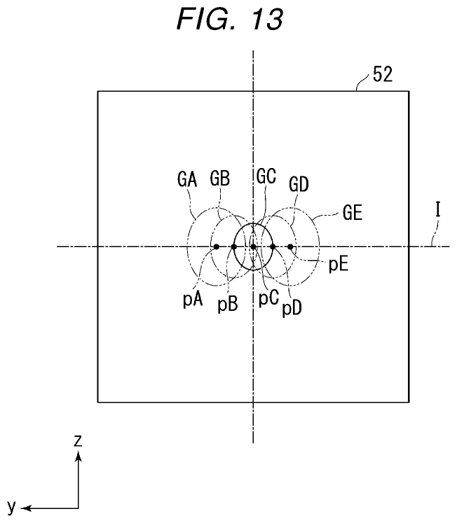

FIG. 12 is a schematic plan view of an example of defocus measurement in the scanning light measuring apparatus of the embodiment. FIG. 13 is a schematic view illustrating an example of an image of scanning light at the time of defocus measurement in the scanning light measuring apparatus of the embodiment.

As illustrated in FIG. 12, in the defocus measurement, in addition to the measurement at the measurement position PC on the image plane I, the measurement is similarly performed at measurement positions PA, PB, PD, and PE separated from the image plane I in the x direction. The movement of the light-receiving element 52 is performed by the measurement control circuit 90 by sending a control signal to the defocus stage 513.

For example, when the incident angle of the optical axis Oc of the scanning light L at the measurement position PC is ϕc, the light-receiving element 52 rotates by ϕd in the xy plane so that the scanning light L is incident at a substantially right angle. When the light-receiving element 52 moves along the x-axis by the defocus stage 513, the scanning position of the scanning light L on the light-receiving element 52 changes according to the inclination of the optical axis Oc.

As illustrated in FIG. 13, for example, the output images at the measurement positions PA, PB, PC, PD, and PE change like GA, GB, GC, GD, and GE, respectively. The scanning light diameter is calculated from each of the image data GA, GB, GC, GD, and GE, and the scanning light diameter during defocus is measured.

The positions of the intensity centers of the image data GA, GB, GC, GD, and GE are, for example, points pA, pB, pC, pD, and pE. The coordinates of the points pA, pB, pC, pD, and pE are calculated based on the position information at each measurement position acquired by the measurement control circuit 90 from the main scanning stage 511 and the defocus stage 513, and the scanning position during defocus is measured.

When the beam waist is calculated from the scanning light diameter at the time of defocus at a plurality of image heights, the curvature of field in the scanning optical system of the optical unit 60 can be measured.

According to the present embodiment, since the support table 54, the light-emission control circuit 93, the light-receiving element 52, the moving mechanism 51, and the measurement control circuit 90 are included, at least one of the scanning light diameter and the scanning position of the scanning light L can be measured while the light-emission control circuit 93 and the measurement control circuit 90 are performing scanning by the optical unit 60 and moving the position of the light-receiving element 52. According to the scanning light measuring apparatus 50, at least one of the scanning light diameter and the scanning position (hereinafter, optical characteristics) of the scanning light L can be measured at a plurality of measurement positions while the light-receiving element 52 is continuously moved in the measurement range, and thus measurement can be performed quickly.

In the present embodiment, for example, quicker measurement is possible as compared with the case where a light-receiving sensor is placed at a measurement position and a stationary beam is aligned with the light-receiving sensor to measure the diameter of the stationary beam and the irradiation position.

According to the present embodiment, the support table 54 can be mounted with the optical unit 60 attached thereto similarly to the image forming apparatus. The scanning light measuring apparatus 50 forms the scanning light L by using the LD driver 71, the motor driver 72, and the synchronous signal generation circuit 73 of the optical unit 60. The scanning light measuring apparatus 50 can measure the optical characteristics of the scanning light L under substantially the same conditions as when the optical unit 60 is mounted on the image forming apparatus.

According to the scanning light measuring apparatus 50, for example, as compared with the case where only the fθ lens is placed on a measurement jig and optical characteristics are measured by using a light source and a mirror for measurement, since the optical characteristics including the influence of the manufacturing accuracy of the housing 61 can be directly measured, the optical characteristics in a state close to the actual use conditions can be accurately measured.

Hereinafter, a modification example of the above-described embodiment will be described.

In the embodiment, the scanning light L of the optical unit 60 is described as being emitted in the horizontal direction. In the case of an optical unit that emits light in a direction other than the horizontal direction, the optical unit or the moving mechanism may be placed so that the relative positional relationship between the scanning light L and the light-receiving element 52 is the same.

For example, when four beams are emitted onto four different image planes from an optical unit like an optical unit used in a color image forming apparatus, a light-receiving element and a moving mechanism may be placed on each image plane.

In the embodiment, it is described that the LD 62 is turned on after a certain time Td from the detection signal of the photo detector 53. In this case, since the irradiation position of the scanning light L in the main scanning direction is substantially constant on the light-receiving element 52, the scanning light L can be reliably received even when the light-receiving surface of the light-receiving element 52 is narrow.

When the light-receiving element 52 has a light-receiving surface with a margin, the LD 62 may be turned on so that the elapsed time from the time of receiving the synchronous detection signal becomes constant. In this case, in FIG. 8, the time td is a designed time until when the scanning light L reaches the measurement position from the time ta. The time td is determined before the start of measurement from the information on the measurement position in the main scanning direction and the information on the scanning speed according to the rotation speed of the polygon motor 65. The measurement control circuit 90 sets the control signal sgd to Hi for the predetermined lighting time T after the time (td−tb) with reference to the detection signal sb.

The main scanning stage 511 moves at a constant speed so that the scanning light L can be received substantially at the center of the light-receiving element 52 at the time td, but there is some speed fluctuation. In the case of the embodiment, the time tb changes according to the speed fluctuation of the main scanning stage 511, and thus the time (tb−ta+Td+T/2) that defines the measurement position changes.

According to the present modification example, the time {tb−ta+(td−tb)+T/2} that defines the measurement position is constant regardless of tb.

When the speed fluctuation of the main scanning stage 511 is small, the measurement positions of the embodiment and the present modification example are substantially the same.

In the embodiment, the main scanning stage 511 of the scanning light measuring apparatus 50 has the linear encoder 5114, the scanning position is obtained based on the information of the linear encoder 5114, and the scanning light diameter is stored in the storage unit 92 for each scanning position.

For example, when it is not necessary to strictly specify a scanning position as in the case of measuring the fθ characteristic, the scanning position may be calculated based on the time measured from the synchronous detection signal. In this case, it is not necessary to strictly measure the movement position of the main scanning stage 511.

As described above, according to at least one embodiment described above, a scanning light measuring apparatus forms scanning light for scanning in a main scanning direction with controllable light-emission time and scanning speed, including a support table on which an optical unit having a synchronous detection sensor for detecting a scanning position of the scanning light is placed, a light-emission control circuit that controls the light-emission time, a light-receiving element that receives the scanning light, a moving mechanism that supports the light-receiving element so as to be movable in the main scanning direction and a rotation direction around an axis orthogonal to the main scanning direction and an optical axis direction of the scanning light, and a measurement control circuit that moves the light-receiving element in the main scanning direction by the moving mechanism, scans the scanning light on the light-receiving element, acquires an output of the light-receiving element, and measures a scanning light diameter of the scanning light based on the output, thereby serving as a scanning light measuring apparatus capable of accurately and quickly evaluating the optical performance of the optical unit that is a unitized exposure apparatus.

While certain embodiments have been described these embodiments have been presented by way of example only, and are not intended to limit the scope of the inventions. Indeed, the novel embodiments described herein may be embodied in a variety of other forms: furthermore various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A scanning light measuring apparatus for observing light scanned in a main scanning direction with controllable light-emission time and scanning speed by an optical unit having a synchronous detection sensor that detects the light, the apparatus comprising:
a support table on which the optical unit is placed;
a light-emission control circuit configured to control the light-emission time based on a synchronous detection signal from the synchronous detection sensor;
a light-receiving element configured to receive the scanning light;
a moving mechanism configured to support the light-receiving element so as to be movable in the main scanning direction and a rotation direction around an axis orthogonal to the main scanning direction and an optical axis direction of the scanning light; and
a measurement control circuit configured to move the light-receiving element in the main scanning direction by the moving mechanism, scan the light-receiving element with the scanning light, acquire an output of the light-receiving element, and measure a scanning light diameter of the scanning light based on the output.

2. The apparatus according to claim 1, wherein the measurement control circuit stores the scanning light diameter for a plurality of scanning positions of the scanning light.

3. The apparatus according to claim 1, wherein
the measurement control circuit rotates the light-receiving element by the moving mechanism so that a light-receiving surface of the light-receiving element at a measurement position of the scanning light is substantially orthogonal to the optical axis direction at least in the main scanning direction.

4. The apparatus according to claim 1, wherein
the moving mechanism supports the light-receiving element so as to be movable in the optical axis direction.

5. The apparatus according to claim 1, wherein
the moving mechanism supports the light-receiving element so as to be movable in a sub-scanning direction intersecting the main scanning direction and the optical axis direction.

6. The apparatus according to claim 1, wherein
the measurement control circuit measures the scanning light diameter at a plurality of measurement positions in the main scanning direction while the light-receiving element is being moved by the moving mechanism in the main scanning direction.

7. The apparatus according to claim 2, wherein
the light-receiving element comprising a two-dimensional image sensor, and
the light-emission control circuit forms the scanning light in a spot shape on the two-dimensional image sensor by a pulse signal.

8. The apparatus according to claim 7, wherein
the measurement control circuit calculates a scanning light diameter in at least one of the main scanning direction and a sub-scanning direction orthogonal to the main scanning direction from image data output by the two-dimensional image sensor.

9. The apparatus according to claim 7, wherein
the measurement control circuit moves the two-dimensional image sensor in the optical axis direction by the moving mechanism and calculates the scanning light diameter at a plurality of positions in the optical axis direction.

10. The apparatus according to claim 7, wherein
the measurement control circuit calculates a scanning position deviation of scanning light in at least one of the main scanning direction and a sub-scanning direction orthogonal to the main scanning direction from image data output by the two-dimensional image sensor.

11. A scanning light measuring method for observing light scanned in a main scanning direction with controllable light-emission time and scanning speed by an optical unit having a synchronous detection sensor that detects the light, the method comprising:
a support table on which the optical unit is placed;
a light-emission control circuit configured to controlling the light-emission time based on a synchronous detection signal from the synchronous detection sensor;
receiving the scanning light by a light-receiving element;
supporting the light-receiving element so as to be movable in the main scanning direction and a rotation direction around an axis orthogonal to the main scanning direction and an optical axis direction of the scanning light;
moving the light-receiving element in the main scanning direction;
scanning the light-receiving element with the scanning light;
acquiring an output of the light-receiving element; and
measuring a scanning light diameter of the scanning light based on the output.

12. The method according to claim 11, further comprising:
storing the scanning light diameter for a plurality of scanning positions of the scanning light.

13. The method according to claim 11, further comprising:
rotating the light-receiving element so that a light-receiving surface of the light-receiving element at a measurement position of the scanning light is substantially orthogonal to the optical axis direction at least in the main scanning direction.

14. The method according to claim 11, further comprising:
supporting the light-receiving element so as to be movable in the optical axis direction.

15. The method according to claim 11, further comprising:
supporting the light-receiving element so as to be movable in a sub-scanning direction intersecting the main scanning direction and the optical axis direction.

16. The method according to claim 11, further comprising:
measuring the scanning light diameter at a plurality of measurement positions in the main scanning direction while the light-receiving element is being moved in the main scanning direction.

17. The method according to claim 12, further comprising:
forming the scanning light in a spot shape on a two-dimensional image sensor by a pulse signal.

18. The method according to claim 17, further comprising:
calculating a scanning light diameter in at least one of the main scanning direction and a sub-scanning direction orthogonal to the main scanning direction from image data output by the two-dimensional image sensor.

19. The method according to claim 17, further comprising:
moving the two-dimensional image sensor in the optical axis direction and calculating the scanning light diameter at a plurality of positions in the optical axis direction.

20. The method according to claim 17, further comprising:
calculating a scanning position deviation of scanning light in at least one of the main scanning direction and a sub-scanning direction orthogonal to the main scanning direction from image data output by the two-dimensional image sensor.
